(19) United States
(12) Patent Application Publication
(10) Pub. No.: US 2021/0249196 A1
(43) Pub. Date: Aug. 12, 2021

(54) ORGANOMETALLIC PEROVSKITE SOLAR CELL, TANDEM SOLAR CELL, AND MANUFACTURING PROCESS THEREFOR

(71) Applicant: Siemens Energy Global GmbH & Co. KG, Munich, Bayern (DE)

(72) Inventors: Seckin Akin, Karaman (TR); Maximilian Fleischer, Höhenkirchen (DE); Michael Grätzel, St-Sulpice (CH); Hui-Seon Kim, Lausanne (CH); Jiyoun Seo, Renens VD (CH); Elfriede Simon, München (DE); Shaik Mohammed Zakeeruddin, Bussigny (CH)

(73) Assignee: Siemens Energy Global GmbH & Co. KG, Munich, Bayern (DE)

(21) Appl. No.: 17/261,001

(22) PCT Filed: Jul. 8, 2019
(86) PCT No.: PCT/EP2019/068247

§ 371 Date: Jan. 16, 2021

(30) Foreign Application Priority Data
Jul. 24, 2018 (DE) 10 2018 212 305.5

(51) Int. Cl. H01G 9/20; H01G 9/00; H01L 27/30; H01L 51/00; H01L 51/42; H01L 51/44

(52) U.S. Cl. CPC H01G 9/2009; H01G 9/0036; H01G 9/2072; H01G 9/2077; H01L 51/0077; H01L 51/0003; H01L 51/4253; H01L 51/448; H01L 27/302

(57) ABSTRACT

An organometallic perovskite solar cell and manufacturing process, in particular a solar cell having a lead or tin organometallic photon absorber layer. The organometallic solar cell includes an absorber layer containing a compound which crystallizes in the perovskite crystal lattice and which includes a lithium-free hole conductor layer.

### CROSS REFERENCE TO RELATED APPLICATIONS

This application is the US National Stage of International Application No. PCT/EP2019/068247 filed 8 Jul. 2019, and claims the benefit thereof. The International Application claims the benefit of German Application No. DE 10 2018 212 305.5 filed 24 Jul. 2018. All of the applications are incorporated by reference herein in their entirety.

### FIELD OF INVENTION

The invention relates to a metal-organic perovskite solar cell, in particular one having a lead- or tin-containing metal-organic photon absorber layer, and also to a process for the production thereof.

### BACKGROUND OF INVENTION

Organic solar cells, also referred to as plastic solar cells, which in contrast to inorganic solar cells can be built up on flexible substrates and films, are known, for example from EP 2498315 A2.

Since the demonstration of the first organic solar cell having a degree of efficiency in the percentage range, organic materials are widely used for various electronic and optoelectronic components. Organic solar cells consist of a sequence of thin layers which typically have a thickness of between 1 nm and 100 μm. The band gap of suitable absorber layers is, for example, at least 1 eV.

There have also already been a wide variety of studies on suitable dopants for the charge carrier transport layers adjoining the absorber layer, for example the hole conductor layer and the electron transport layer. Examples in this respect are EP 2443680, DE 102011003192, DE 102012209520, DE 102014210412 and DE 102015121844.

Organic solar cells have already been the subject of a wide variety of studies since the prospect of making entire glazing units of high-rise buildings usable for power generation by coating with organic solar cells is very attractive worldwide.

The known plastic solar cells have conjugated polymers (hydrocarbon polymers) in combination with small molecules, for example fullerenes, for charge separation as material for the absorber layer.

A structure for a metal-organic perovskite solar cell in which one or more organic-inorganic, here also referred to as “metal-organic”, perovskite layers are arranged between two contact layers, for example electrodes, with which the perovskite layers are arranged in electrical, preferably electrochemical, contact is also known from WO 2014/020499.

The use of metal-organic absorber layers instead of the purely organic absorber layers as described above result in new challenges for the layer sequence of the metal-organic solar cell.

In WO 2014/020499, it is assumed that a hole transport layer as is provided between the absorber layer and the electrode in organic solar cells will be made obsolete by the metal-organic absorber layer.

However, this has been found to be disadvantageous, and therefore the metal-organic solar cell is now also being realized with an absorber layer of a metal-organic material which crystallizes in the perovskite crystal lattice for faster outward transport of the charge carriers separated off by irradiation with photons, with at least one adjoining hole transport layer.

Thus, EP 2898553 A1 discloses a metal-organic “p-i-n” solar cell whose layer sequence comprises at least the following layers: transparent electrode, a hole transport material located thereon, then the absorber layer having a metal-organic absorber material ABX₃ which crystallizes in the three-dimensional perovskite lattice, then an electron transport layer and the counterelectrode. The content of the patent applications to which introductory reference is made here is hereby incorporated into the disclosure of the present patent application because these and the other documents cited by way of introduction here are assumed as part of the accumulated technical knowledge of a person working in this technical field.

A hole transport layer which can be used in a solar cell described here is, for example, composed of “2,2′,7,7′-tetrakis(N,N-di-p-methoxyphenylamine)-9,9′-spirobifluorene” or “SpiroOMeTad” for short with very high, for example 30 mol % and above, concentrations of a weak dopant containing lithium ions.

However, the use of such high doping concentrations of lithium in a metal-organic solar cell results in the disadvantage that these layers are highly hygroscopic and have only a low stability.

### SUMMARY OF INVENTION

It is therefore an object of the present invention to provide alternative p-dopants whose stability within the hole conductor layer and the entire metal-organic solar cell is greater instead of or in addition to the known lithium-containing p-dopant.

This object is achieved by the subject matter of the present invention as is disclosed by the description, the figure and the claims.

Accordingly, the present invention provides a metal-organic solar cell having at least two contact layers and, adjoining these, in each case a semiconducting layer in a layer stack having a centrally arranged absorber layer composed of a metal-organic material which crystallizes in the three-dimensional perovskite crystal lattice, where the absorber layer comprises lead and/or tin as central atom and a halide as anion in a metal-organic compound, characterized in that the at least one semiconducting layer between the absorber layer and the anode is a hole-conducting layer which comprises a zinc- and/or bismuth-containing dopant.

In addition, the invention provides a tandem solar cell comprising either two metal-organic solar cells or at least one metal-organic solar cell having a zinc- and/or bismuth-containing dopant in the hole conductor layer.

Finally, the invention provides a process for producing a layer body forming a tandem solar cell, in which a layer stack comprising two solar cells is present, where a lower solar cell and an upper solar cell are produced by the production of sequential layers, characterized in that at least one of the solar cells is a metal-organic solar cell as is provided by the invention.

The term metal-organic compound will here be used to refer to what is known as a complex. For example, the compound CH₃NH₃PbI₃ which crystallizes in the perovskite crystal lattice is a prime example of such a compound. A unit cell in which the lead is located centrally as the “central atom” in a cube and the organic ligands, for example the CH₃NH₃, form the eight corners of the cube can be recognized in the crystal lattice. An anion, for example a halide anion such as iodide, is then located centrally in each face of the cube. When many such cells adjoin one another in the crystal lattice, this results in the stoichiometry having an empirical formula of CH₃NH₃PbI₃.

As regards the tandem solar cell, it has been found to be advantageous for the two solar cells in the tandem solar cell to be matched to one another in respect of their absorption spectrum, so that a maximum radiation spectrum is absorbed. It is particularly advantageous here for the tandem solar cell to be formed by two metal-organic solar cells, for example by the two solar cells differing in terms of the composition of the material which forms the absorber layer.

In addition, the combination of a metal-organic solar cell as is provided by the invention with a c-Si solar cell has also been found to be advantageous. A c-Si solar cell is a solar cell which comprises crystalline silicon in the absorber layer. In this case, the metal-organic solar cell is advantageously located on top, closer to the sun.

In particular, the c-Si solar cell is, for example, used as a substrate to build up a metal-organic solar cell as is provided by the invention.

The individual layers of the layer body which forms a metal-organic solar cell or a tandem solar cell comprising a metal-organic solar cell can be produced by a wet-chemical method, for example by spin coating, for example but not necessarily using a solvent. Production by means of vapor deposition, chemical or physical, is possible as an alternative.

It is generally recognized by the invention that, contrary to expectations which would have lead a doping with zinc- and/or bismuth-compounds in a spiro-OMeTAD hole conductor layer adjoining a perovskite absorber layer composed of lead and/or tin complexes to be considered to be unstable, stable dopants for stable hole conductor layers can be produced from zinc and/or bismuth salts with, for example, superacids.

The dopant advantageously comprises an anion of a superacid in addition to the zinc and/or bismuth cation.

In this respect, the hole conductor layer comprises at least one matrix and a dopant, the latter based here on zinc and/or bismuth. The addition of customary additives is, however, also encompassed by the scope of the invention.

A suitable matrix material for the hole transport layer of a metal-organic perovskite solar cell is, for example, an organic conductor, for example “2,2′,7,7′-tetrakis(N,N-di-p-methoxy-phenylamine)-9,9′-spirobifluorene” or “spiro-OMeTAD”. It has been able to be shown by measurements that small concentrations, for example from 0.05 to 10 mol %, in particular from 0.1 to 7 mol % and advantageously even only from 0.1 to 2 mol %, of a dopant containing zinc and/or bismuth in a spiro-OMeTAD layer are sufficient to produce the necessary current densities in the hole conductor layer of the solar cell.

In the deposition of the hole conductor layer by a wet chemical method, i.e. from solution, the dopant concentration is, in particular, set via the proportion by mass of, for example, a superacid salt and the proportion by mass of the matrix material in the solution before deposition. The volume concentration of the p-dopant in the finished, deposited hole conductor layer can deviate from this concentration.

Using the class of materials according to the invention of zinc and/or bismuth salts, for example of superacids, as dopants, a wet-chemical deposition method with respect to the deposition from the gas phase to produce the individual layers of the layer stack is advantageous.

The photon-absorbing properties in particular for use of the p-dopant in metal-organic solar cells can be greatly improved by the novel materials for p-doping. A high conductivity is achieved even at low doping concentrations.

Nonlimiting examples of superacids in the context of the present patent application are:

Inorganic:
fluorosulfonic acid (HSO₃F)
fluoroantimonic acid (HSbF₆)
tetrafluoroboric acid (HBF₄)
hexafluorophosphoric acid (HPF₆)
trifluoromethylsulfonic acid (HSO₃CF₃)

Organic:
pentacyanocyclopentadiene (HC₅(CN)₅)
partially fluorinated or perfluorinated derivatives of pentaphenylcyclopentadiene
pentatrifluoromethylpentadiene or analogous derivatives
partially fluorinated or perfluorinated derivatives of tetraphenylboric acid or cyano derivatives thereof
partially fluorinated or perfluorinated derivatives of arylsulfonic acids or cyano derivatives thereof
partially fluorinated or perfluorinated derivatives of arylphosphonic acids or cyano derivatives thereof
anions of carboranes, for example [C₂B₁₀H₁₀]⁻² or [C₁B₁₁H₁₀]⁻

Trifluoromethylsulfonic acid (HSO₃CF₃) is a particularly suitable representative thereof.

Polymeric matrix materials for hole transporters which can be wet-chemically deposited to produce the hole conductor layer of the solar cell are, in addition to the abovementioned “2,2′,7,7′-tetrakis(N,N-di-p-methoxyphenylamine)-9,9′-spirobifluorene” or “spiro-OMeTAD”, also in particular:
PEDOT (poly(3,4-ethylenedioxythiophene))
PVK (poly(9-vinylcarbazole))
PTPD (poly(N,N-bis(4-butylphenyl)-N,N-bis(phenyl)benzidine))
P3HT (poly(3-hexylthiophene))
PANI (polyaniline)
PTAA (poly[bis(4-phenyl)(2,4,6-trimethylphenyl)amine])
and also
9,9-bis [4-(N,N-bis-biphenyl-4-yl-amino)phenyl]-9H-fluorene
and/or
4,4′,4″-tris(N-(2-naphthyl)-N-phenyl-amino)triphenylamine.

Mixtures of the polymeric hole transport materials mentioned are also suitable for the purposes of the invention.

As solvent for wet-chemical processing, advantage is given to using organic solvents such as:
benzene,
chlorobenzene,
chloroform,
toluene,
THF,
methoxypropyl acetate,
anisole,
acetonitrile,
phenetole or
dioxane.

A further particular advantage of the invention is that the class of materials of the superacid salts which is suitable for the p-doping can be deposited together with the hole conductor matrix from the same solvent. This represents a significant simplification of the deposition process for producing the metal-organic solar cell.

In addition, the doping on the hole conductor layer can be produced more easily, in particular at a lower process temperature, using the zinc and/or bismuth salts as dopants than the already known lithium-doped hole transport layers. The temperature is a quite sensitive factor in the production of the metal-organic solar cell because the organic ligands and the crystal structure naturally react very sensitively to an increase in temperature. Furthermore, it is not necessary for oxygen to be present in processing to achieve the doping effect in the case of these doping materials. This is advantageous since oxygen has an adverse effect on other parts of the layer system of the metal-organic solar cell. For example, the production of a hole conductor layer admixed with a lithium-containing dopant requires the use of additives such as tert-butylpyridine (TBP). Together with the highly hygroscopic nature of the lithium compounds, this leads to indirect oxidation by atmospheric oxygen.

In an advantageous embodiment of the tandem solar cell, the metal-organic solar cell is the upper solar cell on which the photons impinge first. Here there are two embodiments, namely 2-terminal and 4-terminal structures of a tandem cell, in each case as a function of the number of contact points of the tandem solar cell.

As absorber layer of the metal-organic solar cell, advantage is given to using a layer having an ABX₃ stoichiometry which crystallizes in the three-dimensional perovskite crystal lattice.

For example, a CH₃NH₃PbX₃ and/or CH₃NH₃SnX₃, where X can be a halide or pseudohalide, for example selected from the group consisting of fluoride, chloride, cyanide, isocyanide, bromide and/or iodide and any combinations thereof, is used as metal-organic ABX₃ compound. The perovskite absorber can have very different compositions and comprise, for example, “mixing cations” such as MA, FA and/or Cs.

The halides/pseudohalides are present here as anions in the crystal lattice, while the organic ligand (CH₃NH₃)⁺ is, like the lead or tin, present as cation. The material of the absorber layer can also comprise, partly or entirely, other compounds such as those mentioned below in a nonexhaustive listing:
FA_{0.81}Cs_{0.15}PbI_{2.51}Br_{0.45}
FA_{0.9}Cs_{0.1}PbI₃
Cs_{0.05}MA_{0.1}FA_{0.85}Pb(I_{0.85}Br_{0.15})₃
Cs_{0.05}MA_{0.1}FA_{0.85}Pb(I_{0.85}Br_{0.15})₃

For the purposes of the invention, mixtures of the compounds mentioned are also possible for the absorber material.

It has surprisingly been found that the replacement of lithium by zinc and/or bismuth in the dopant or in the hole conductor layer not only increases the stability of the hole conductor layer to some extent but initial tests have also indicated that the zinc and/or bismuth dopants even in significantly smaller concentrations in the hole-conducting layers also lead to higher open circuit voltages, a high fill factor and a significantly higher photon conversion efficiency (PCE) of the solar cells. Zn(TFSI)₂, for example, is obviously more active than LiTFSI in the hole conductor layer, for example in spiro-MeOTAD, it conducts the charge carriers more quickly and leads to a higher level of free charge carriers therein.

Measurements at the EPFL, Lausanne, have shown that the TSFI derivatives of zinc and bismuth which are here used for the first time in combination with spiro-MeOTAD produce significant electrical improvements in the hole conductor layer, which cannot be explained by an improved conductivity alone.

### BRIEF DESCRIPTION OF THE DRAWINGS

FIG. 1 shows the structure of a metal-organic solar cell 1 in the n i p layout.

FIG. 2 shows the rise in the open circuit voltage of a metal-organic solar cell on changing from a lithium-doped hole conductor layer to a zinc-doped hole conductor layer.

FIG. 3 shows four different characteristic photovoltaic parameters.

FIG. 4 shows measurements on individual hole conductor layers without a solar cell structure.

FIG. 5 compares the stability of the hole conductor layers produced using zinc on the one hand and using lithium on the other hand.

### DETAILED DESCRIPTION OF INVENTION

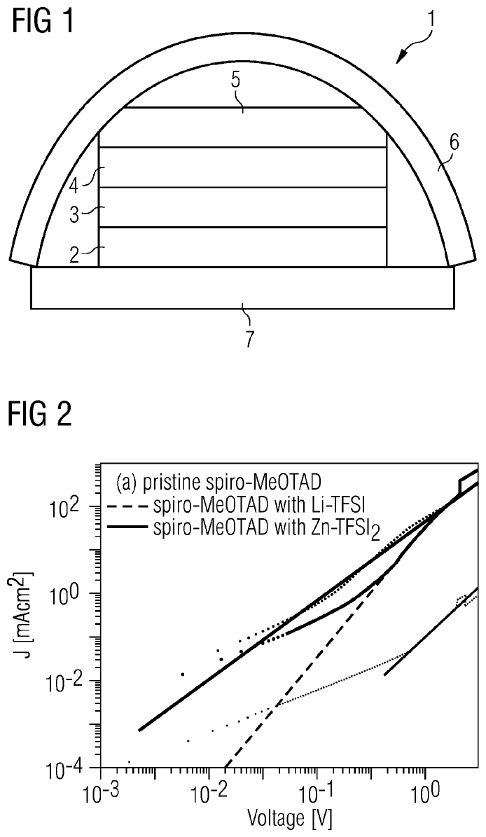

FIG. 1 shows the structure of a metal-organic solar cell 1 in the n-i-p layout, comprising at least the following layers: a transparent conductive electrode 7, for example an electrode composed of doped indium-tin oxide or another transparent conductive layer. This can have been applied to a support such as glass or be self-supporting.

On this layer, there is an n-conducting layer 2, for example composed of titanium dioxide. On top of this, there is the absorber layer, for example the layer 3 composed of CH₃NH₃PbI₃ and/or CH₃NH₃SnI₃ present in the three-dimensional perovskite structure. The absorber layer 3 can be planar or be present in the form of a framework structure here. Adjoining this layer, there is the hole transport layer 4 which in the present case is composed of a matrix material, for example the spiro-MeOTAD, with a dopant containing zinc and/or bismuth, in particular with Zn(TFSI)₂ and/or Bi(TFSI)₃, as is known from DE 10 2015 121844.

In the case of the dopant Zn(TFSI)₂ and/or Bi(TFSI)₃, a thin barrier layer, not shown here, is provided between the hole conductor layer 4 and the absorber layer 3 in an advantageous embodiment. This can be advantageous if the dopant has a tendency to diffuse into the absorber layer.

Instead of or together with the Zn(TFSI)₂, the following are, for example, also present as dopant: Bi(3,5-TFMBZ)₃, bismuth(III) tris(3,5-bistrifluoromethyl)benzoate, Bi(4-pFbz)₃, bismuth(III) tris(4-pentafluoro)benzoate, K(TFSI), K(I) bis(trifluoromethanesulfonyl)imide and/or Zn(II) bis(trifluoromethanesulfonyl)imide and/or sodium(I) bis(trifluoromethane-sulfonyl)imide.

Furthermore, trifluoromethanesulfonates such as Zn(TFMS)₂ can also advantageously be used as dopant. As an alternative or in addition, it is also possible to utilize “ionic liquids” as effective dopants.

Finally, the counterelectrode, for example composed of aluminum, silver and/or gold, is additionally present on the hole conductor layer 4.

The total structure is advantageously protected against moisture and/or air by an encapsulation 6.

FIG. 2 shows the rise in the open circuit voltage of a metal-organic solar cell on changing from a lithium-doped hole conductor layer to a zinc-doped hole conductor layer.

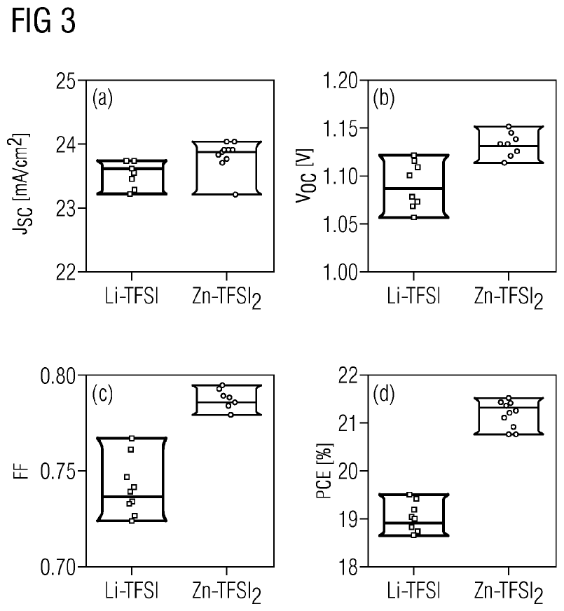

FIG. 3 shows four different characteristic photovoltaic parameters (JSC (short circuit current), VOC (open circuit voltage), FF (fill factor) and PCE (photocurrent efficiency)) of perovskite solar cells, here as a comparison between a perovskite solar cell having spiro-MeOTAD/LiTFSI (black) and spiro-MeOTAD/Zn(TFSI)₂ (red) as hole conductor layer.

These measurements in each case compare the metal-organic solar cells with lithium-doped and zinc-doped hole conductor layers with an otherwise identical structure and under the same measurement conditions. Thus, these measurements clearly show that the solar cells constructed with a zinc-doped hole conductor layer are at least equal to the conventional lithium-doped solar cells. This is all the more astonishing since the doping concentration decreases significantly from lithium to zinc and/or bismuth, which brings about a significant economic advantage.

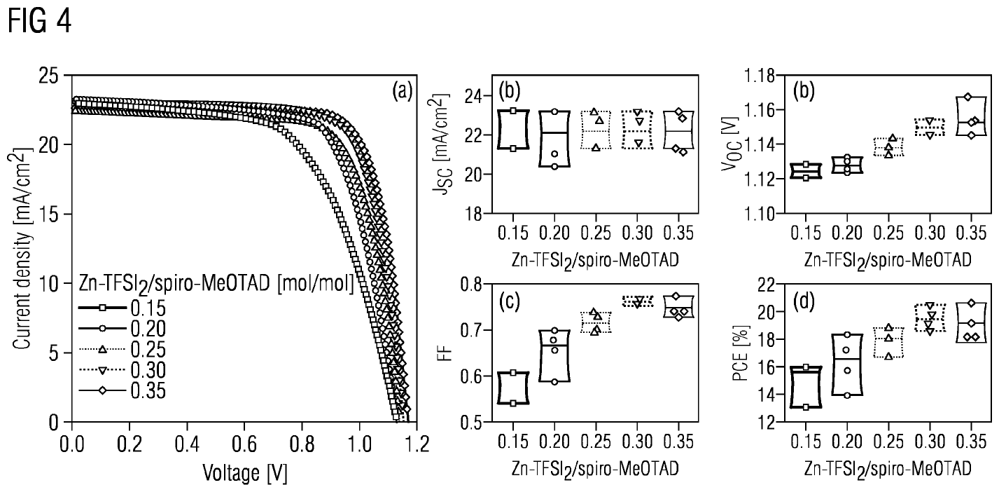

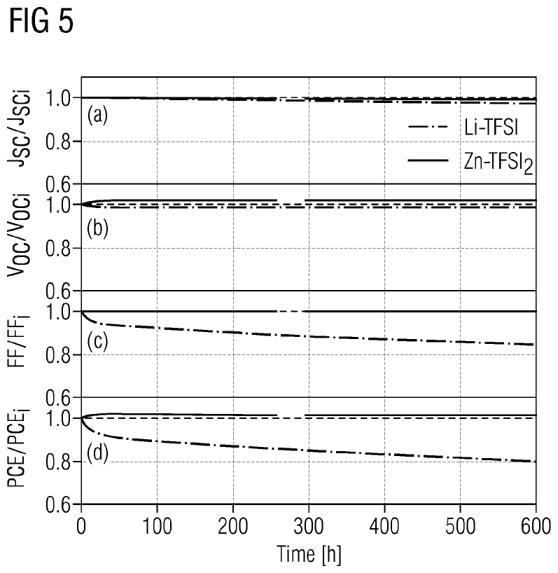

FIG. 4 shows measurements on individual hole conductor layers without a solar cell structure. The current density at various doping concentrations at various voltages can be seen in the figure, with the result that above 0.2 mol of dopant per mole of matrix compound, it is obviously no longer possible to achieve any significant increase in the current density by increasing the doping concentration.

FIG. 4 shows not only the current-voltage curves, which can be seen at left, but also, at right, the corresponding photovoltaic parameters such as JSC, VOC, FF and PCE as a function of the concentration of the dopant Zn(TFSI)₂ in the matrix material spiro-MeOTAD.

It is conspicuous here that, in particular, the “fill factor” was improved significantly. The fill factor refers to the quotient of the maximum power of a solar cell at the maximum power point and the product of open circuit voltage and short circuit current.

Overall, it can be concluded from the measurements that the metal-organic solar cells which are built up with a hole conductor layer having the zinc- and/or bismuth-based dopant according to the invention and have an absorber layer composed of a material which crystallizes in the three-dimensional perovskite structure display very good efficiency of the light-into-electricity conversion.

Finally, the stability of the hole conductor layers produced using zinc on the one hand and using lithium on the other hand is compared in FIG. 5. It can be seen that the conventional lithium-doped hole conductor layers are far less stable than the corresponding hole conductor layers containing zinc and/or bismuth. This is related, inter alia, to the fact that the small lithium ion naturally diffuses more easily and quickly in the case of a temperature increase and/or in an electric field and thus decreases the homogeneity of the hole conductor layers. In the case of the PCE (power conversion efficiency)/PCE measurement, in particular, it can be clearly seen how the efficiency of the lithium-doped hole conductor layer decreases with increasing number of hours.

The present invention for the first time discloses a metal-organic solar cell comprising an absorber layer containing a compound which crystallizes in the perovskite crystal lattice and having a low-lithium hole conductor layer.

1. A metal-organic solar cell comprising:
at least two contact layers and, adjoining these, in each case a semiconducting layer in a layer stack having a centrally arranged absorber layer composed of a metal-organic material which crystallizes in the three-dimensional perovskite crystal lattice,
where the absorber layer comprises lead as central atom and a halide as anion in a metal-organic compound,
wherein the at least one semiconducting layer between the absorber layer and the anode is a hole-conducting layer which comprises a zinc-containing dopant.

2. A metal-organic solar cell comprising:
at least two contact layers and, adjoining these, in each case a semiconducting layer in a layer stack having a centrally arranged absorber layer composed of a metal-organic material which crystallizes in the three-dimensional perovskite crystal lattice,
where the absorber layer comprises tin as central atom and a halide as anion in a metal-organic compound,
wherein the at least one semiconducting layer between the absorber layer and the anode is a hole-conducting layer which comprises a bismuth-containing dopant.

3. The solar cell as claimed in claim 1,
wherein the zinc compound in the dopant is the salt of a superacid.

4. The solar cell as claimed in claim 1,
wherein the solar cell comprises a diffusion barrier layer between the absorber layer and a semiconducting layer.

5. The solar cell as claimed in claim 4,
wherein the diffusion barrier layer has a layer thickness of less than 150 nm.

6. The solar cell as claimed in claim 1,
which in the matrix material of the hole conductor layer comprises one or more compounds selected from the group consisting of the following compounds:
spiro-OMeTAD—2,2′,7,7′-tetrakis(N,N-di-p-methoxyphenylamine)-9,9′-spirobifluorene,
PEDOT—poly(3,4-ethylenedioxythiophene),
PVK—poly(9-vinylcarbazole),
PTPD—poly(N,N-bis(4-butylphenyl)-N,N-bis(phenyl)benzidine),
P3HT—poly(3-hexylthiophene),
PANI—polyaniline,
PTAA—poly[bis(4-phenyl)(2,4,6-trimethylphenyl)amine],
9,9-bis [4-(N,N-bis-biphenyl-4-yl-amino)phenyl]-9H-fluorene,
4,4′,4″-tris(N-(2-naphthyl)-N-phenyl-amino)triphenylamine
and/or ionic liquids, and also mixtures of the abovementioned compounds.

7. The solar cell as claimed in claim 1,
wherein the absorber layer comprises a metal complex having tin and/or lead as central atom which contains at least one anion in the form of a halide or pseudohalide, selected from the group of the following elements: fluoride, chloride, bromide, iodide, cyanide, isocyanide.

8. The solar cell as claimed in claim 1,
wherein the absorber layer comprises a metal complex having tin and/or lead as central atom to which a (CH₃NH₃)⁺ ligand is coordinated.

9. A tandem solar cell comprising:
at least two superposed solar cells in a layer stack,
wherein one solar cell is a metal-organic solar cell as claimed in claim 1.

10. The tandem solar cell as claimed in claim 9,
wherein the metal-organic solar cell is the upper solar cell on which the photons impinge first.

11. The tandem solar cell as claimed in claim 9,
which comprises a solar cell having crystalline silicon in the absorber layer.

12. The tandem cell as claimed in claim 9,
which comprises two metal-organic solar cells,
wherein the two solar cells differ in terms of the composition of the material which forms the absorber layer.

13. A process for producing a layer body forming a tandem solar cell, comprising:
producing a layer stack comprising two solar cells by layer deposition in a wet-chemical process,
wherein a lower solar cell and an upper solar cell are produced by the production of sequential layers,
wherein one of the solar cells is a metal-organic solar cell as claimed in claim 1.

14. The solar cell as claimed in claim 2,
wherein the bismuth compound in the dopant is the salt of a superacid.

15. The solar cell as claimed in claim 2,
wherein the solar cell comprises a diffusion barrier layer between the absorber layer and a semiconducting layer.

16. The solar cell as claimed in claim 15,
wherein the diffusion barrier layer has a layer thickness of less than 150 nm.

17. The solar cell as claimed in claim 2,
which in the matrix material of the hole conductor layer comprises one or more compounds selected from the group consisting of the following compounds:
spiro—OMeTAD-2,2′,7,7′-tetrakis(N,N-di-p-methoxyphenylamine)-9,9′-spiro-bifluorene,
PEDOT—poly(3,4-ethylenedioxythiophene),
PVK—poly(9-vinylcarbazole),
PTPD—poly(N,N-bis(4-butylphenyl)-N,N-bis(phenyl)benzidine),
P3HT—poly(3-hexylthiophene),
PANI—polyaniline,
PTAA—poly[bis(4-phenyl)(2,4,6-trimethylphenyl)amine],
9,9-bis [4-(N,N-bis-biphenyl-4-yl-amino)phenyl]-9H-fluorene,
4,4′,4″-tris(N-(2-naphthyl)-N-phenyl-amino)triphenylamine
and/or ionic liquids, and also mixtures of the abovementioned compounds.

18. The solar cell as claimed in claim 2,
wherein the absorber layer comprises a metal complex having tin and/or lead as central atom which contains at least one anion in the form of a halide or pseudohalide, selected from the group of the following elements: fluoride, chloride, bromide, iodide, cyanide, isocyanide.

19. The solar cell as claimed in claim 2,
wherein the absorber layer comprises a metal complex having tin and/or lead as central atom to which a (CH₃NH₃)⁺ ligand is coordinated.

20. A tandem solar cell comprising
at least two superposed solar cells in a layer stack,
wherein one solar cell is a metal-organic solar cell as claimed in claim 2.

21. The tandem solar cell as claimed in claim 20,
wherein the metal-organic solar cell is the upper solar cell on which the photons impinge first.

22. The tandem solar cell as claimed in claim 20,
which comprises a solar cell having crystalline silicon in the absorber layer.

23. The tandem cell as claimed in claim 20,
which comprises two metal-organic solar cells,
wherein the two solar cells differ in terms of the composition of the material which forms the absorber layer.
